(19) United States
(12) Patent Application Publication
(10) Pub. No.: US 2025/0393403 A1
(43) Pub. Date: Dec. 25, 2025

(54) DISPLAY DEVICE AND ELECTRONIC DEVICE INCLUDING SAME

(71) Applicant: Samsung Display Co., LTD., Yongin-si (KR)

(72) Inventor: Jang Hyun KIM, Yongin-si (KR)

(21) Appl. No.: 19/078,703

(22) Filed: Mar. 13, 2025

(30) Foreign Application Priority Data
Jun. 19, 2024 (KR) 10-2024-0079324

(51) Int. Cl. H10K 59/122

(52) U.S. Cl. CPC H10K 59/122

(57) ABSTRACT

A display device includes a display panel including a display area, in which a first stack including a lower light emitting layer and a second stack including an upper light emitting layer are disposed, and a non-display area outside the display area, where a pixel defining film partitioning a plurality of light emitting areas and a plurality of spacers disposed at intervals on the pixel defining film are disposed in the display area, and a spacer of the plurality of spacers includes a first test pattern, and a second test pattern is disposed in the non-display area. The first test pattern and the second test pattern are configured in a way such that a deposition defect of each of the first stack and the second stack is detected based on the first test pattern and the second test pattern.

This application claims priority to Korean Patent Application No. 10-2024-0079324, filed on Jun. 19, 2024, and all the benefits accruing therefrom under 35 U.S.C. 119, the content of which in its entirety is herein incorporated by reference.

### BACKGROUND

### 1. Field

Embodiments of the disclosure relate to a display device and an electronic device including the display device.

### 2. Description of the Related Art

As an information society develops, the demand for a display device for displaying an image is increasing in various forms. The display device may be a flat panel display, such as a liquid crystal display, a field emission display, or a light emitting display panel. The light emitting display device may include an organic light emitting diode (OLED) display device including an OLED element as a light emitting element or a light emitting diode (LED) display device including an inorganic light emitting diode element such as an LED as a light emitting element.

A display device using a two stack tandem OLED structure, in which an upper light emitting layer is stacked on a lower light emitting layer, is being developed. The display device using the two stack tandem OLED structure may provide a high-brightness screen by combining light generated from two layers (i.e., the lower light emitting layer and the upper light emitting layer).

### SUMMARY

Aspects of the disclosure provide a display device that is easy to test for deposition defects in upper and lower light emitting layers when manufacturing a display device having a two stack tandem OLED structure, and an electronic device including the display device.

According to an embodiment of the disclosure, a display device includes a display panel including a display area, in which a first stack including a lower light emitting layer and a second stack including an upper light emitting layer are disposed, and a non-display area outside the display area, where a pixel defining film partitioning a plurality of light emitting areas and a plurality of spacers disposed at intervals on the pixel defining film are disposed in the display area, and a spacer of the plurality of spacers includes a first test pattern, and a second test pattern is disposed in the non-display area, where the first test pattern and the second test pattern are configured in a way such that a deposition defect of each of the first stack and the second stack is detected based on the first test pattern and the second test pattern.

In an embodiment, the first test pattern may include a trench formed on an upper surface of the spacer.

In an embodiment, the trench may have a quadrangular shape in a plan view.

In an embodiment, the first test pattern may further include a first test organic film disposed on the trench in a first shape, and a second test organic film disposed on the first test organic film in a second shape, where the first test organic film may be deposited in a same process as the lower light emitting layer, and the second test organic film may be deposited in a same process as the upper light emitting layer.

In an embodiment, the first shape may be a circular shape with a diameter smaller than a length and a width of the trench in the plan view, and the second shape may be a quadrangular shape having an area smaller than an area of the trench in the plan view.

In an embodiment, the second test pattern may include a first test element group pattern deposited in a same process as the lower light emitting layer, and a second test element group pattern deposited in a same process as the upper light emitting layer.

In an embodiment, the plurality of spacers may include a first spacer including the first test pattern, and a second spacer which does not include the first test pattern.

In an embodiment, the first spacer may be disposed at predetermined intervals within the display area.

In an embodiment, the display area may be divided into m×n imaginary partial areas, and the first spacer is disposed one by one in each of the imaginary partial areas.

In an embodiment, the first test pattern may include a plurality of trenches defined on an upper surface of the spacer.

According to an aspect of the disclosure, an electronic device comprises a display panel including a display area, in which a first stack including a lower light emitting layer and a second stack including an upper light emitting layer are disposed, and a non-display area outside the display area, where a pixel defining film partitioning a plurality of light emitting areas and a plurality of spacers disposed at intervals on the pixel defining film are disposed in the display area, and a spacer of the plurality of spacers includes a first test pattern for testing deposition defects of each of the first stack and the second stack, and a second test pattern for testing deposition defects of each of the first stack and the second stack is disposed in the non-display area.

In an embodiment, the first test pattern may include a trench defined on an upper surface of the spacer.

In an embodiment, the trench may have a quadrangular shape when viewing the spacer from above.

In an embodiment, the first test pattern may further include a first test organic film disposed on the trench in a first shape, and a second test organic film disposed on the first test organic film in a second shape, where the first test organic film may be deposited in a same process as the lower light emitting layer, and the second test organic film may be deposited in a same process as the upper light emitting layer.

In an embodiment, the first shape may be a circular shape with a diameter smaller than a length and a width of the trench in the plan view, and the second shape may be a quadrangular shape having an area smaller than an area of the trench in the plan view.

In an embodiment, the second test pattern may include a first test element group pattern deposited in a same process as the lower light emitting layer, and a second test element group pattern deposited in a same process as the upper light emitting layer.

In an embodiment, the plurality of spacers may include a first spacer including the first test pattern, and a second spacer which does not include the first test pattern.

In an embodiment, the first spacer may be disposed at predetermined intervals within the display area.

In an embodiment, the display area may be divided into m×n imaginary partial areas, and the first spacer may be disposed one by one in each of the imaginary partial areas.

In an embodiment, the first test pattern may include a plurality of trenches defined on an upper surface of the spacer.

In the display device and the electronic device including the display device according to embodiments, when manufacturing the display device having two stack tandem OLED structure, deposition defects in the upper and lower light emitting layers may be easily tested based on the first and second test patterns.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other features of embodiments of the disclosure will become more apparent by describing in detail embodiments thereof with reference to the attached drawings, in which:

FIG. 1 is a schematic perspective view of a display device according to an embodiment;

FIG. 2 is a schematic cross-sectional view of the display device according to an embodiment;

FIG. 3 is a conceptual view of a display unit and a touch driver according to an embodiment;

FIG. 4 is a schematic plan view illustrating a display unit of the display device according to an embodiment;

FIG. 5 is a plan view illustrating a portion of a display area of a display panel according to an embodiment;

FIG. 6 is a cross-sectional view illustrating light emitting areas of the display device according to an embodiment;

FIG. 7 is a cross-sectional view of a portion of the display panel according to an embodiment;

FIG. 8 is a plan view of a portion of a display panel including a first spacer and a second spacer according to an embodiment;

FIG. 9 is an example of determining that a deposition process is normal using a first test pattern according to an embodiment;

FIG. 10 is an example of determining that the deposition process is defective using the first test pattern according to an embodiment;

FIG. 11 is a cross-sectional view of a first spacer including a first test pattern according to another embodiment;

FIGS. 12 and 13 are plan views of a display panel illustrating a first test pattern and a second test pattern according to an embodiment;

FIG. 14 is a process flowchart illustrating a method of manufacturing a display device according to an embodiment;

FIG. 15 is a plan view of a first mask according to an embodiment;

FIG. 16 is a plan view of a second mask according to an embodiment; and

FIG. 17 is a configuration view illustrating test equipment for a display device according to an embodiment.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. Like reference numerals refer to like elements throughout.

It will also be understood that when a layer is referred to as being “on” another layer or substrate, it can be directly on the other layer or substrate, or intervening layers may also be present therebetween. In contrast, when an element is referred to as being “directly on” another element, there are no intervening elements present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

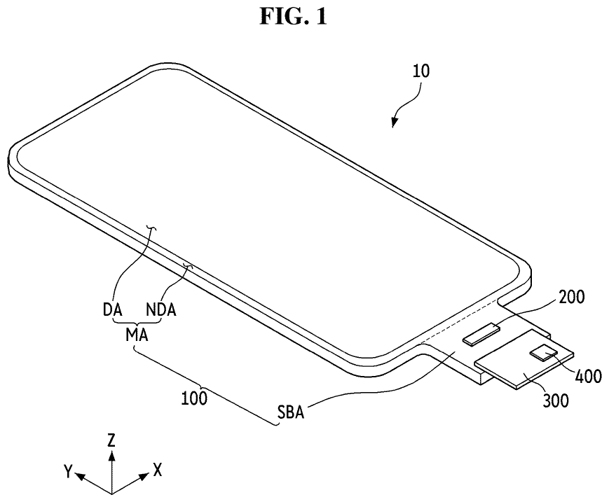

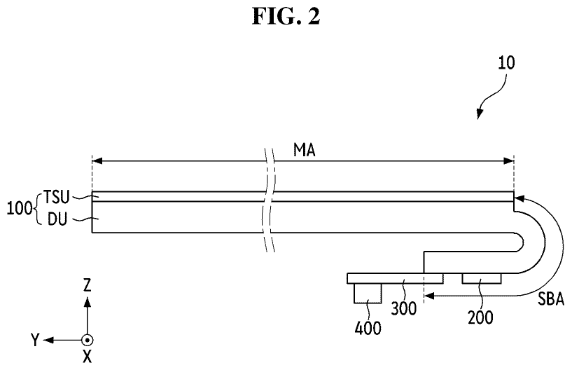

FIG. 1 is a schematic plan view of a display device according to an embodiment. FIG. 2 is a schematic cross-sectional view of the display device according to an embodiment.

In the drawings, a first direction X is a direction parallel to one side of a display device 10 in a plan view, and refers to a direction of a short side of the display device 10. A second direction Y is a direction parallel to the other side in contact with one side of the display device 10 in the plan view, and refers to a direction of a long side of the display device 10. A third direction Z may refer to a thickness direction of the display device 10. However, it will be understood that the directions mentioned in the embodiments refer to relative directions, and the embodiments are not limited to the mentioned directions.

The display device 10 may include various electronic devices that provide a display screen. In an embodiment, for example, the display device 10 may be applied to portable electronic devices such as mobile phones, smartphones, tablet personal computers (PCs), mobile communication terminals, electronic notebooks, electronic books, portable multimedia players (PMPs), navigation systems, and ultra mobile PCs (UMPCs). In an embodiment, for example, the display device 10 may be applied to a display unit DU of a television, a laptop computer, a monitor, a billboard, or the Internet of Things (IoT). In addition, the display device 10 may be applied to wearable devices such as smart watches, watch phones, glasses-type displays, and head mounted displays (HMDs).

Referring to FIG. 1, an embodiment of the display device 10 may be formed in a planar shape similar to a quadrangle. In an embodiment, for example, the display device 10 may have a planar shape similar to a quadrangle having a short side in the first direction X and a long side in the second direction Y. A corner where the short side in the first direction X and the long side in the second direction Y meet may be rounded to have a predetermined curvature or may have a right angled shape. The planar shape of the display device 10 is not limited to the quadrangle, and may have a shape similar to other polygons, circles, or ovals.

At least one of the front and rear surfaces of the display device 10 may be a display surface. Here, the “front surface” refers to a surface positioned on one side of one plane and positioned in the third direction Z in the drawing, and the “rear surface” refers to a surface positioned on the other side of one plane and positioned in a direction opposite to the third direction Z in the drawing. The display device 10 may be a double-sided display device 10 in which display is performed on both the front and rear surfaces, but hereinafter, for convenience of description, embodiments in which the display surface is positioned on the front surface of the display device 10 will be mainly described an example.

In an embodiment, the display device 10 includes a display panel 100 that provides a display screen, a display driving circuit 200, a circuit board 300, and a touch driving circuit 400. The touch driving circuit 400 is a component configured to sense a user's touch input and may be referred to as a “touch sensing device.”

The display panel 100 may be formed in a planar shape similar to a quadrangle. In an embodiment, for example, the display panel 100 may have a planar shape similar to a quadrangle having a short side in the first direction X and a long side in the second direction Y. A corner where the short side in the first direction X and the long side in the second direction Y meet may be rounded to have a predetermined curvature or may have a right angled shape. The planar shape of the display panel 100 is not limited to the quadrangle, and may have a shape similar to other polygons, circles, or ovals. In addition, the display panel 100 may also be flexibly formed to be flexibly bent or curved.

The display panel 100 may include a main area MA and a sub-area SBA.

The main area MA may include a display area DA including pixels displaying an image, and a non-display area NDA disposed around the display area DA. The display area DA may emit light from a plurality of light emitting areas or a plurality of opening areas. In an embodiment, for example, the display panel 100 may include a pixel circuit including switching elements, a pixel defining film defining the light emitting areas or the opening areas, and a self-light emitting element.

The non-display area NDA may be an area outside the display area DA. The non-display area NDA may be defined as an edge area of the main area MA of the display panel 100. The non-display area NDA may include a gate driver (not illustrated) that supplies gate signals to gate lines (not illustrated) of the display panel 100.

The sub-area SBA may extend from one side of the main area MA. The sub-area SBA may be bent to overlap the main area MA in a third direction Z. The sub-area SBA may include a pad portion connected to the display driving circuit 200 and the circuit board 300.

The display panel 100 includes a display unit DU and a touch unit TSU.

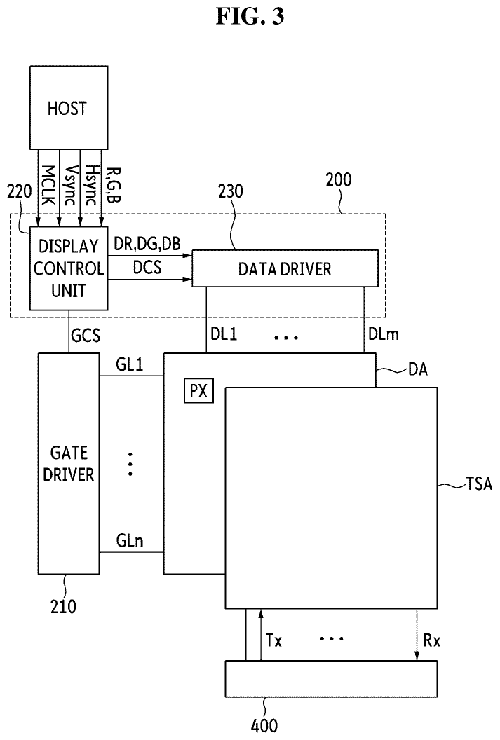

The display unit DU may include a plurality of pixels (PX in FIG. 3). The pixel PX is a basic unit for displaying a screen. One pixel PX may include, but is not limited to, a red sub-pixel, a green sub-pixel, and a blue sub-pixel. The plurality of pixels PX may be alternately arranged in a plan view. In an embodiment, for example, the pixels PX may be arranged in a matrix form, but are not limited thereto.

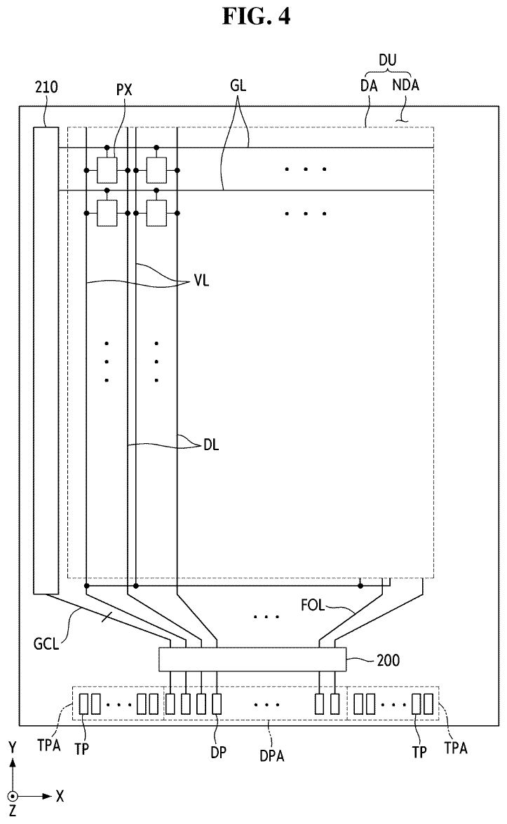

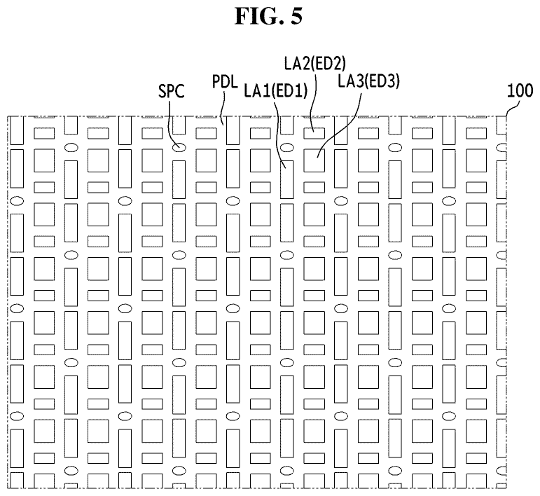

The touch unit TSU may be disposed on the display unit DU, but the disclosure is not limited thereto. In an embodiment, for example, the touch unit TSU may be formed like the display unit DU using an in-cell touch method. The touch unit TSU may include a plurality of touch electrodes (SEN in FIG. 5) for sensing a user's touch (or a pen touch) in a capacitive manner, a plurality of touch driving lines (TL in FIG. 5) connecting the plurality of touch electrodes SEN and the touch driving circuit 400, and a plurality of touch sensing lines (RL in FIG. 5). The touch unit TSU, which is a layer that senses a touch input, may function as a touch member. The touch unit TSU may determine whether the touch input has been made and calculate a corresponding position as touch input coordinates. A detailed description of the display unit DU and the touch unit TSU will be described later with reference to FIGS. 4 to 7.

The display unit DU and the touch unit TSU may also be disposed to overlap each other. In an embodiment, for example, the display area DA may be an area that displays a screen and may be an area that senses a touch input.

The sub-area SBA of the display panel 100 may extend from one side of the main area MA. The sub-area SBA may include a flexible material that may be bent, folded, rolled, or the like. In an embodiment, for example, a portion of the sub-area SBA may be bent on one side of the main area MA, and another portion of the sub-area SBA extending from the bent portion of the sub-area SBA may overlap the main area MA in a third direction (Z-axis direction). The sub-area SBA may include a pad portion connected to the display driving circuit 200 and the circuit board 300.

The display driving circuit 200 may be disposed in the sub-area SBA of the display panel 100. In addition, the display driving circuit 200 may be formed as an integrated circuit (IC) and mounted on the display panel 100 by a chip on plastic (COP) method or a chip on glass (COG) method.

The display driving circuit 200 may output data signals and voltages for driving the display panel 100. The display driving circuit 200 may supply data voltages to data lines (not illustrated) of the display panel 100. The display driving circuit 200 may supply a power voltage to a power line of the display panel 100 and may supply gate control signals to a gate driver.

The circuit board 300 may be disposed in the sub-area SBA of the display panel 100. Lead lines (not illustrated) of the circuit board 300 may be electrically connected to the pad portion of the display panel 100. The circuit board 300 may be a flexible film such as a flexible printed circuit board, a printed circuit board, or a chip on film.

The circuit board 300 may include a plurality of conductive lines (not illustrated) for transmitting signals from a main circuit board (not illustrated) to the display driving circuit 200, or electrically connecting the touch driving circuit 400 to a plurality of first electrodes TE and a plurality of second electrodes RE of the touch unit TSU.

In the disclosure, the first electrode TE may be referred to as “touch driving electrode.” In the disclosure, the second electrode RE may be referred to as “touch sensing electrode.”

The touch driving circuit 400 may be disposed in the sub-area SBA of the display panel 100. Alternatively, the touch driving circuit 400 may be mounted on the circuit board 300.

The touch driving circuit 400 may determine whether a touch input is made and calculate touch coordinates, based on sensing the amount of change in capacitance between the plurality of touch electrodes. The touch driving circuit 400 may be formed as an integrated circuit (IC) and mounted on the display panel 100 by a chip on plastic (COP) method or a chip on glass (COG) method.

FIG. 3 is a conceptual view of a display unit and a touch driver according to an embodiment. FIG. 4 is a schematic plan view illustrating a display unit of the display device according to an embodiment.

Referring to FIGS. 3 and 4, an embodiment of the display device 10 includes a display panel 100 including a plurality of pixels PX, a display driving circuit 200, a gate driver 210 and a touch driving circuit 400. The display driving circuit 200 and the touch driving circuit 400 may operate based on a control signal or command signal from a host. In an embodiment, for example, the hose may be a processor. According to an embodiment, the touch driving circuit 400 may be controlled by the display driving circuit 200.

The display driving circuit 200 may include a data driver 230 and a display control unit 220.

The display control unit 220 may receive input data (R, G, and B) and a timing control signal from the outside (e.g., the host). The timing control signal may include a vertical synchronization signal Vsync indicating one frame period, a horizontal synchronization signal Hsync indicating one horizontal period, and a main clock MCLK repeated at a predetermined period. The input data (R, G, and B) may be RGB data including red image data, green image data, and blue image data. The display control unit 220 may generate output data signals DR, DG, and DB and an internal control signal using the received input data (R, G, and B) and timing control signal. The internal control signal includes a data control signal DCS and a gate control signal GCS.

The display control unit 220 may control an operation of the data driver 230 by providing the data control signal DCS to the data driver 230. The display control unit 220 may control an operation of the gate driver 210 by providing the gate control signal GCS to the gate driver 210.

The data driver 230 may receive the output data signals DR, DG, and DB and the data control signal DCS from the display control unit 220. The data driver 230 may generate a data signal using the received output data signals DR, DG, and DB and data control signal DCS. The data driver 230 may provide the generated data signal to the display panel 100. The data driver 230 may provide the data signal to the plurality of pixels PX through a plurality of data lines DL1 to DLm (e.g., DL in FIG. 4) formed in the display panel 100.

The gate driver 210 may receive the gate control signal GCS from the display control unit 220. The gate driver 210 may generate a gate signal using the received gate control signal GCS. The gate driver 210 may provide the generated gate signal to the display panel 100. The gate driver 210 may provide the gate signal to the plurality of pixels PX through a plurality of gate lines GL1 to GLn (e.g., GL in FIG. 4) formed in the display panel 100. Here, m and n are natural numbers greater than 1.

In an embodiment, as shown in FIG. 3, the display driving circuit 200 does not include the gate driver 210, but the disclosure is not limited thereto. In an embodiment, for example, the gate driver 210 may be included in the display driving circuit 200 that controls the operation of the display panel 100. The gate driver 210, the data driver 230, and the display control unit 220 may be formed as an integrated circuit (IC). In an embodiment, the gate driver 210 may be formed on the display panel 100 during a thin film transistor (TFT) process of the display panel 100. The display control unit 220 and the data driver 230 may be merged to form (or integrated into) a timing controller embedded driver integrated circuit (TED).

The display panel 100 may include a plurality of pixels PX connected to the plurality of data lines DL1 to DLm and the plurality of gate lines GL1 to GLn.

A frame frequency at which the display driving circuit 200 drives the display panel 100 may be variable. In an embodiment, for example, the frame frequency may be variable within the range of about 1 hertz (Hz) to about 240 Hz depending on the selection of the host or the user. The display driving circuit 200 may drive at about 60 Hz for one period and change the frame frequency to about 120 Hz for another period as desired.

The touch sensing area TSA may include a plurality of touch electrodes. The touch sensing area TSA may receive an electrical signal Tx from the touch driving circuit 400. The touch sensing area TSA may sense a touch input by transmitting the electrical signal Rx sensed from the plurality of touch electrodes to the touch driving circuit 400.

Referring to FIG. 4, the display unit DU may include a display area DA and a non-display area NDA. The display unit DU may include a plurality of sub-pixels PX arrange din the display area DA, and a plurality of gate lines GL and a plurality of data lines DL connected to the plurality of sub-pixels PX.

The plurality of gate lines GL may supply the gate signal received from the gate driver 210 to the plurality of sub-pixels PX. The plurality of gate lines GL may extend in the first direction X and may be spaced apart from each other in the second direction Y intersecting the first direction X.

The plurality of data lines DL may supply the output data signals DR, DG, and DB and the data signal received from the display driving circuit 200 to the plurality of sub-pixel PX. The plurality of data lines DL may extend in the second direction Y and may be spaced apart from each other in the first direction X.

The non-display area NDA may surround the display area DA. In an embodiment, for example, the non-display area NDA may include a gate driver 210 that applies the gate signals to the plurality of gate lines GL, fan-out lines FOL that connect the plurality of data lines DL to the display driving circuit 200, and a display pad portion DP connected to the circuit board 300.

The display driving circuit 200 may supply the gate control signal GCS to the gate driver 210 through a gate control line GCL. The gate driver 210 may generate a plurality of gate signals based on gate control signal GCS, and may sequentially supply the plurality of gate signals to the plurality of gate lines GL according to a set order.

The display driving circuit 200 may supply a first power voltage to first power lines VL and a second power voltage to second power lines (not illustrated) through the data driver 230. Each of the plurality of sub-pixels PX may be supplied with the first power voltage through the first power line VL and the second power voltage through the second power line. The first power voltage may be a predetermined high level voltage, and the second power voltage may be a voltage lower than the first power voltage.

The display pad area DPA and the touch peripheral area TPA may be disposed at an edge of the display panel 100. The display pad area DPA may include a plurality of display pad portions DP. The plurality of display pad portions DP may be connected to a main processor (not illustrated) through the circuit board 300. The plurality of display pad portions DP may be connected to the circuit board 300 to receive digital video data and supply the digital video data to the display driving circuit 200.

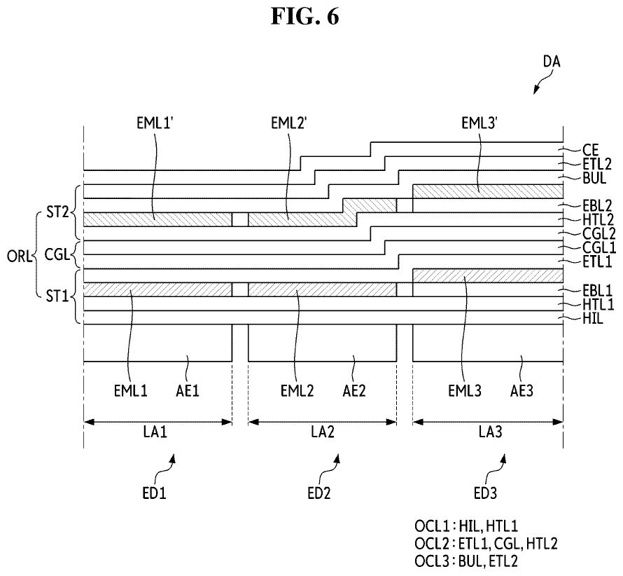

FIG. 5 is a plan view illustrating a portion of a display area of a display panel according to an embodiment. FIG. 6 is a cross-sectional view illustrating light emitting areas of the display device according to an embodiment. FIG. 6 schematically illustrates an anode electrode AE, an organic film layer ORL, and a cathode electrode CE of organic light emitting elements ED1, ED2, and ED3 disposed on the display panel 100.

Referring to FIGS. 5 and 6, in an embodiment, a plurality of light emitting areas LA1, LA2, and LA3 and a pixel defining film PDL partitioning the plurality of light emitting areas LA1, LA2, and LA3 are disposed in the display area DA of the display panel 100. In such an embodiment, the pixel defining film PDL may cover boundaries between the plurality of light emitting areas LA1, LA2, and LA3 with openings defined therethrough to expose the plurality of light emitting areas LA1, LA2, and LA3. A plurality of spacers SPC are disposed with intervals on the pixel defining film PDL The plurality of spacers SPC may be disposed on the pixel defining film PDL according to a predetermined arrangement. The plurality of light emitting areas LA1, LA2, and LA3 may include a first light emitting area LA1, a second light emitting area LA2, and a third light emitting area LA3.

Anode electrodes AE1, AE2, and AE3 may be disposed in the first light emitting area LA1, the second light emitting area LA2, and the third light emitting area LA3, respectively. The first anode electrode AE1 may be disposed to overlap the first light emitting area LA1, the second anode electrode AE2 may be disposed to overlap the second light emitting area LA2, and the third anode electrode AE3 may be disposed to overlap the third light emitting area LA3.

In some embodiments, the first anode electrode AE1, the second anode electrode AE2, and the third anode electrode AE3 may be reflective electrodes. In such embodiments, the first anode electrode AE1, the second anode electrode AE2, and the third anode electrode AE3 may be metal layers including metals such as Ag, Mg, Al, Pt, Pd, Au, Ni, Nd, Ir, and Cr. In another embodiment, the first anode electrode AE1, the second anode electrode AE2, and the third anode electrode AE3 may further include a metal oxide layer stacked on the metal layer. In an embodiment, the first anode electrode AE1, the second anode electrode AE2, and the third anode electrode AE3 may have a multilayer structure, for example, a two-layer structure of ITO/Ag, Ag/ITO, ITO/Mg, or ITO/MgF₂, or a three-layer structure such as ITO/Ag/ITO.

In some embodiments, the organic film layer ORL may have a structure in which a plurality of light emitting layers are disposed to overlap (or stacked with) each other, for example, a tandem structure. In an embodiment, for example, the organic film layer ORL may include a first stack ST1 including lower light emitting layers EML1, EML2, and EML3, a second stack ST2 positioned on the first stack ST1 and including upper light emitting layers EML1′, EML2′, and EML3′, and a charge generation layer CGL positioned between the first stack ST1 and the second stack ST2. The first stack ST1 and the second stack ST2 may be disposed to overlap each other in a thickness direction.

The lower light emitting layers EML1, EML2, and EML3 and the upper light emitting layers EML1′, EML2′, and EML3′ may be disposed to overlap each other.

In some embodiments, a first lower light emitting layer EML1 and a first upper light emitting layer EML′ may emit light of a first color, for example, blue light. A second lower light emitting layer EML2 and a second upper light emitting layer EML2′ may emit light of a second color, for example, red light. A third lower light emitting layer EML3 and a third upper light emitting layer EML3′ may emit light of a third color, for example, green light. That is, emission light finally emitted from the organic film layer ORL may be blue light in the first light emitting area LA1, red light in the second light emitting area LA2, and green light in the third light emitting area LA3.

The charge generation layer CGL may be disposed between the first stack ST1 and the second stack ST2. The charge generation layer CGL may serve to inject charges into each light emitting layer. The charge generation layer CGL may serve to adjust a charge balance between the first stack ST1 and the second stack ST2. The charge generation layer CGL may include an n-type charge generation layer CGL1 and a p-type charge generation layer CGL2. The p-type charge generation layer CGL2 may be disposed on the n-type charge generation layer CGL1, and may be positioned between the n-type charge generation layer CGL1 and the second stack ST2.

The charge generation layer CGL may have a structure in which the n-type charge generation layer CGL1 and the p-type charge generation layer CGL2 are bonded to each other. The n-type charge generation layer CGL1 may be disposed closer to the anode electrodes AE1, AE2, and AE3 among the anode electrodes AE1, AE2, and AE3 and the cathode electrode CE. The p-type charge generation layer CGL2 is disposed closer to the cathode electrode CE among the anode electrodes AE1, AE2, and AE3 and the cathode electrode CE. The n-type charge generation layer CGL1 supplies electrons to the lower light emitting layers EML1, EML2, and EML3 adjacent to the anode electrodes AE1, AE2, and AE3, and the p-type charge generation layer CGL2 supplies holes to the upper light emitting layer EML1′, EML2′, and EML3′ included in the second stack ST2. The charge generation layer CGL may be disposed between the first stack ST1 and the second stack ST2 to provide the charges to each of the light emitting layers, thereby increasing emission efficiency and lowering a driving voltage.

The first stack ST1 may be disposed on the first anode electrode AE1, the second anode electrode AE2, and the third anode electrode AE3, and may further include a first hole transporting layer HTL1, a first electron block layer EBL1, and a first electron transporting layer ETL1.

The first hole transporting layer HTL1 may be disposed on the first anode electrode AE1, the second anode electrode AE2, and the third anode electrode AE3, respectively. The first hole transporting layer HTL1 may serve to smoothly transport holes and may include a hole transporting material.

The first electron block layer EBL1 may be positioned on the first hole transporting layer HTL1, and may be positioned between the first hole transporting layer HTL1 and the lower light emitting layers EML1, EML2, and EML3. The first electron block layer EBL1 may include a hole transporting material and a metal or a metal compound to effectively prevent electrons generated in the lower light emitting layers EML1, EML2, and EML3 from passing over to the first hole transporting layer HTL1. In some embodiments, the first hole transporting layer HTL1 and the first electron block layer EBL1 that are described above may also be formed as a single layer in which the respective materials are mixed. In an embodiment, for example, the first electron block layer EBL1 may be omitted from at least one of the first to third light emitting areas LA1, LA2, and LA3.

The first electron transporting layer ETL1 may be disposed on the lower light emitting layers EML1, EML2, and EML3 and may be disposed between the charge generation layer CGL and the lower light emitting layers EML1, EML2, and EML3.

The second stack ST2 may be disposed on the charge generation layer CGL and may further include a second hole transporting layer HTL2, a second electron block layer EBL2, a buffer layer BUL, and a second electron transporting layer ETL2.

The second hole transporting layer HTL2 may be positioned on the charge generation layer CGL. The second hole transporting layer HTL2 may be made of the same material as the first hole transporting layer HTL1, or may also include one or more materials selected from the materials exemplified as the material included in the first hole transporting layer HTL1. The second hole transporting layer HTL2 may be made as or defined by a single layer or a plurality of layers, that is, second hole transporting layer HTL2 may have a single layer structure or a multi-layer structure.

The second electron block layer EBL2 may be positioned on the second hole transporting layer HTL2, and may be disposed between the second hole transporting layer HTL2 and the upper light emitting layers EML1′, EML2′, and EML3′. The second electron block layer EBL2 may include or be made of a same material as the first electron block layer EBL1 and have a same structure as the first electron block layer EBL1, or may also include at least one selected from the materials listed above as the material included in the first electron block layer EBL1. In an embodiment, for example, the second electron block layer EBL2 may be omitted from at least one of the first to third light emitting areas LA1, LA2, and LA3.

The second electron transporting layer ETL2 may be disposed on the upper light emitting layers EML1′, EML2′, and EML3′ and may be disposed between the upper light emitting layers EML1′, EML2′, and EML3′ and the cathode electrode CE. The second electron transporting layer ETL2 may include or be made of a same material as the first electron transporting layer ETL1 and have a same structure as the first electron transporting layer ETL1, or may also include at least one selected from the materials listed above as the material included in the first electron transporting layer ETL1. The second electron transporting layer ETL2 may be made as or defined by a single layer or a plurality of layers.

The buffer layer BUL may be disposed between the upper light emitting layers EML1′, EML2′, and EML3′ and the second electron transporting layer ETL2. The buffer layer BUL may effectively prevent holes from passing over to the cathode electrode CE from the upper light emitting layers EML1′, EML2′, and EML3′. The buffer layer BUL may include materials with hole properties, for example, a hole transporting layer material, but is not limited thereto.

The cathode electrode CE may be disposed on the organic film layer ORL described above. The cathode electrode CE may have semi-permeability or permeability.

The first anode electrode AE1, the organic film layer ORL, and the cathode electrode CE may constitute (or collectively define) a first light emitting element ED1, the second anode electrode AE2, the organic film layer ORL, and the cathode electrode CE may constitute a second light emitting element ED2, and the third anode electrode AE3, the organic film layer ORL, and the cathode electrode CE may constitute a third light emitting element ED3. The first light emitting element ED1, the second light emitting element ED2, and the third light emitting element ED3 may each emit emission light. In an embodiment, for example, the first light emitting element ED1 may emit blue light, the second light emitting element ED2 may emit red light, and the third light emitting element ED3 may emit green light.

The charge generation layer CGL may be a common layer that extends to the plurality of light emitting areas and is continuously disposed. In an embodiment, for example, in FIG. 5, the charge generation layer CGL may be a common layer continuously disposed in the first light emitting area LA1, the second light emitting area LA2, and the third light emitting area LA3. In addition, the hole injection layer HIL, the first hole transporting layer HTL1, the first electron transporting layer ETL1, the second hole transporting layer HTL2, the buffer layer BUL, and the second electron transporting layer ETL2 may also be a common layer that extends to the plurality of light emitting areas and is continuously disposed.

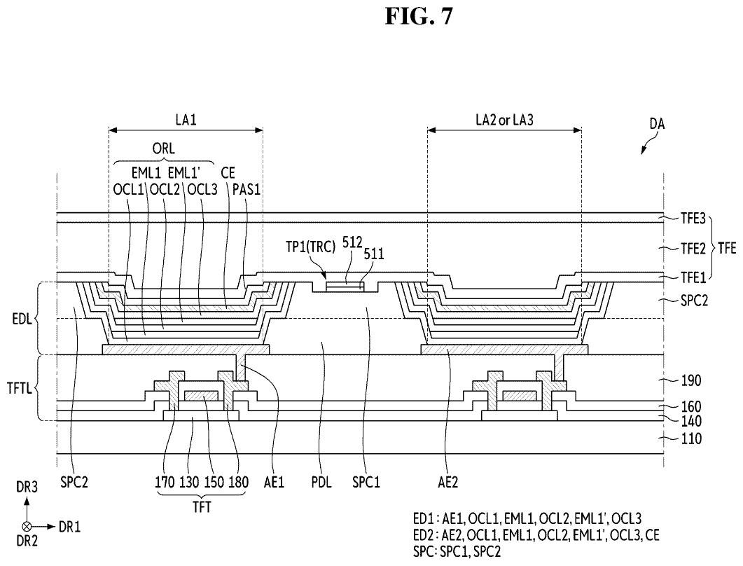

FIG. 7 is a cross-sectional view of a portion of the display panel according to an embodiment.

Referring to FIG. 7, the display panel 100 of the display device 10 according to an embodiment may include a substrate 110, and a thin film transistor layer TFTL and a light emitting element layer EDL disposed on the substrate 110.

The substrate 110 may be a rigid substrate or a flexible substrate that may be bent, folded, or rolled.

The thin film transistor layer TFTL may be disposed on the substrate 110. The thin film transistor layer TFTL may include a thin film transistor TFT, a gate insulating layer 140, an interlayer insulating layer 160, and a planarization layer 190.

The thin film transistor TFT may include an active layer 130, a gate electrode 150, a source electrode 170, and a drain electrode 180. The active layer 130 may include polycrystalline silicon, single crystal silicon, an oxide semiconductor, or the like. In an embodiment where the semiconductor layer includes an oxide semiconductor, the active layer 130 may include a plurality of conductive regions and a channel region therebetween. The oxide semiconductor may be an oxide semiconductor containing indium (In). In another embodiment, the active layer 130 may also include polycrystalline silicon. The polycrystalline silicon may be formed by crystallizing amorphous silicon. In such an embodiment, the conductive region of the active layer 130 may be a doped region doped with impurities.

In an embodiment, a light blocking layer (not shown) for blocking external light incident to the active layer 130 may be disposed between the substrate 110 and the active layer 130. In an embodiment where the light blocking layer is disposed between the substrate 110 and the active layer 130, the light blocking layer may be disposed to overlap the active layer 130 and may include or be formed of an opaque metal material that blocks transmission of light.

The gate insulating layer 140 may be disposed on the active layer 130. The gate insulating layer 140 may be disposed on the substrate 110 while including the active layer 130. The gate insulating layer 140 may be formed as an inorganic layer including an inorganic film, for example, silicon oxide (SiO₂), silicon nitride (SiN), or silicon oxynitride (SiON), or may be formed in a structure in which such inorganic films are stacked.

The gate electrode 150 may be disposed on the gate insulating layer 140. A gate line and one electrode of a storage capacitor may be further disposed in (or directly on) a same layer as the gate electrode 150.

The interlayer insulating layer 160 may be disposed on the gate electrode 150. The interlayer insulating layer 160 may serve as an insulating film between the gate electrode 150 and other layers disposed thereon. In addition, the interlayer insulating layer 160 may be disposed to cover the gate electrode 150 and serve to protect the gate electrode 150. The interlayer insulating layer 160 may be formed as an inorganic layer including an inorganic material, for example, silicon oxide (SiO₂), silicon nitride (SiNx), or silicon oxynitride (SiON), or may be formed in a structure in which such inorganic materials are stacked.

The source electrode 170 and the drain electrode 180 may be disposed on the interlayer insulating layer 160. Each of the source electrode 170 and the drain electrode 180 may be connected to the active layer 130 through a contact hole defined or formed through the gate insulating layer 140 and the interlayer insulating layer 160.

The planarization layer 190 for planarizing a level difference caused by the thin film transistor TFT may be disposed on the source electrode 170 and the drain electrode 180. The planarization layer 190 may be provided with a contact hole for connecting the anode electrodes AE1 and AE2 of the light emitting elements ED1 and ED2 to the thin film transistor TFT.

The light emitting element layer EDL may be disposed on the planarization layer 190. The light emitting element layer EDL may include light emitting elements ED1 and ED2 and a pixel defining film PDL. The light emitting elements ED1 and ED2 may include anode electrodes AE1 and AE2, an organic film layer ORL, and a cathode electrode CE. In an embodiment, for example, the first light emitting element ED1 may include a first anode electrode AE1, an organic film layer ORL, and a cathode electrode CE, and the second light emitting element ED2 may include a second anode electrode AE2, an organic film layer ORL, and a cathode electrode CE.

The anode electrodes AE1 and AE2 may serve as pixel electrodes or first electrodes, and may be connected to the drain electrode 180 of the thin film transistor TFT through the contact hole of the planarization layer 190. The anode electrodes AE and AE2 may be reflective electrodes that reflect light emitted from the organic film layer ORL.

The pixel defining film PDL may be disposed to cover edges of the anode electrodes AE1 and AE2 on the planarization layer 190 to partition each of the light emitting areas LA1 and LA2.

A spacer SPC may be disposed on the pixel defining film PDL. The spacer SPC may protrude in the third direction DR3 on the pixel defining film PDL.

At least one spacer SPC1 of the plurality of spacers SPC may include a first test pattern TP1 for testing (or detecting) deposition defects in each of the first stack ST1 and the second stack ST2. That is, the first test pattern TP1 may be configured in a way such that deposition defects in each of the first stack ST1 and the second stack ST2 may be tested. Here, the first test pattern TP1 includes a trench TRC formed on an upper surface of the spacer SPC1.

The spacer SPC1 including the first test pattern TP1 may be referred to as a first spacer SPC1. A first test organic film 511 deposited in a same process as the lower light emitting layers EML1, EML2, and EML3 is deposited on the trench TRC, which is the first test pattern TP1 of the first spacer SPC1, in a first shape, and a second test organic film 512 deposited in a same process as the upper light emitting layers EML1′, EML2′, and EML3′, is deposited on the first test organic film 511 in a second shape.

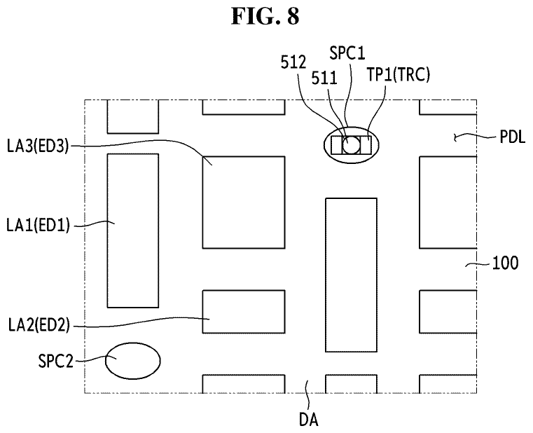

As will be described later with reference to FIG. 8, the trench TRC of the first test pattern TP1 has a quadrangular shape when the first spacer SPC1 is viewed from above or in a plan view. In addition, the first shape of the first test organic film 511 is a circular shape with a diameter smaller than a length and width of the trench TRC, and the second shape of the second test organic film 512 is a quadrangular shape having an area smaller than an area of the trench TRC.

The organic film layer ORL may be disposed on the anode electrodes AE1 and AE2 and the pixel defining film PDL. The organic film layer ORL may include a hole injection layer HIL, a first hole transporting layer HTL1, a first electron block layer EBL1, a charge generation layer CGL, a second hole transporting layer HTL2, a second electron block layer EBL2, a buffer layer BUL, and a second electron transporting layer ETL2. In the first light emitting area LA1, a first lower light emitting layer EML1 may be disposed between the first electron block layer EBL1 and the charge generation layer CGL, and a first upper light emitting layer EML1′ may be disposed between the second electron block layer EBL2 and the second electron transporting layer ETL2. In the second light emitting area LA2, a second lower light emitting layer EML2 may be disposed between the first electron block layer EBL1 and the charge generation layer CGL, and a second upper light emitting layer EML2′ may be disposed between the second electron block layer EBL2 and the second electron transporting layer ETL2. In FIG. 7, the hole injection layer HIL and the first hole transporting layer HTL1 are represented by a first common layer OCL1, the charge generation layer CGL, the first electron transporting layer ETL1, and the second hole transporting layer HTL2 are represented by a second common layer OCL2, and the buffer layer BUL and the second electron transporting layer ETL2 are represented by a third common layer OCL3.

The cathode electrode CE may be disposed on the organic film layer ORL. The cathode electrode CE may be disposed to cover the organic film layer ORL. The cathode electrode CE may be a cathode electrode that injects electrons into the light emitting elements ED1 and ED2, and may be a second electrode. In addition, the cathode electrode CE may be a common layer commonly provided in each of the light emitting elements ED1 and ED2.

The cathode electrode CE may be disposed separately on the spacer SPC. For example, the cathode electrode CE is disposed in each of the first light emitting area LA1 and the second light emitting area LA2, but may be disposed to be separated from each other on the spacer SPC disposed between the first light emitting area LA1 and the second light emitting area LA2. The cathode electrode CE may be disposed to non-overlap an upper surface of the spacer SPC in the third direction DR3.

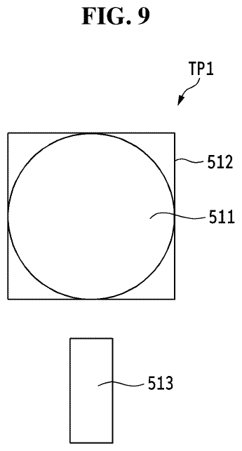

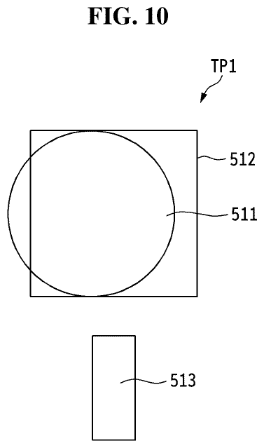

FIG. 8 is a plan view of a portion of a display panel including a first spacer and a second spacer according to an embodiment. FIG. 9 is an example of determining that a deposition process is normal using a first test pattern according to an embodiment. FIG. 10 is an example of determining that the deposition process is defective using the first test pattern according to an embodiment.

Referring to FIGS. 8 to 10, in an embodiment, a plurality of spacers SPC disposed in the display area DA of the display panel 100 include a first spacer SPC1 including the first test pattern TP1 and a second spacer SPC2 that does not include the first test pattern TP1.

The first spacer SPC1 may be disposed at specified or predetermined intervals within the display area, and the second spacer SPC2 may be defined as the remaining spacer excluding the first spacer SPC1.

The first test pattern TP1 includes a trench TRC defined or formed on the upper surface of the first spacer SPC1.

The trench TRC has a quadrangular shape when viewing the first spacer SPC1 from above or in a plan view.

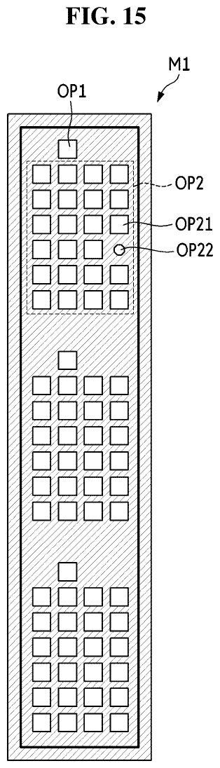

On the trench TRC, a first test organic film 511 deposited in a same process as the lower light emitting layers EML1, EML2, and EML3 is deposited in a first shape. In an embodiment, a first mask (M1 in FIG. 15) may include a structure for depositing the first test organic film 511 in the first shape. In addition, on the first test organic film 511, a second test organic film 512 deposited in a same process as the upper light emitting layer EML1′, EML2′, and EML3′ is deposited in a second shape. In an embodiment, a second mask (M2 in FIG. 15) may include a structure for depositing the second test organic film 512 in the second shape.

In an embodiment, the first shape is a circular shape with a diameter smaller than a length and a width of the trench TRC, and the second shape is a quadrangular shape having an area smaller than an area of the trench TRC.

As illustrated in FIG. 9, it may be determined that the deposition process is normal using the first test pattern TP1. In an embodiment, for example, when the deposition process of the upper light emitting layers EML1′, EML2′, EML3′ and the lower light emitting layers EML1, EML2, and EML3 is normally performed, the first test organic film 511 and the second test organic film 512 deposited on the first test pattern TP1 may be aligned with the center of a reference pattern 513.

As illustrated in FIG. 10, it may be determined that the deposition process is defective using the first test pattern TP1. In an embodiment, for example, when the deposition process of the upper light emitting layers EML1′, EML2′, and EML3′ and the lower light emitting layers EML1, EML2, and EML3 is abnormally performed, the first test organic film 511 and the second test organic film 512 deposited on the first test pattern TP1 may not be aligned with the center of the reference pattern 513. As such, according to an embodiment of the disclosure, it may be determined whether or not the deposition process of the upper light emitting layer EML1′, EML2′, and EML3′ and the lower light emitting layer EML1, EML2, and EML3 is defective by forming the first test pattern TP1 in at least one spacer of the plurality of spacers SPC.

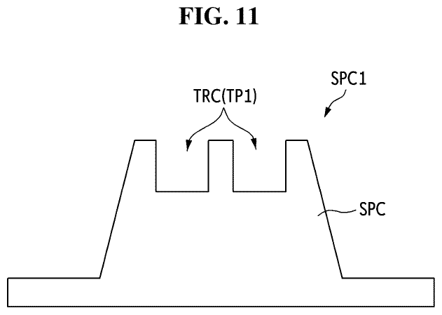

FIG. 11 is a cross-sectional view of a first spacer SPC1 including a first test pattern TP1 according to another embodiment.

The embodiment of FIG. 11 is substantially the same as the embodiment of FIG. 7 except that the first spacer SPC1 including the first test pattern TP1 includes a plurality of trenches TRC. In an embodiment, for example, the first spacer SPC1 may include a plurality of trenches TRC as the first test pattern TP1. The first test organic film 511 and the second test organic film 512 may be deposited in the plurality of trenches TRC.

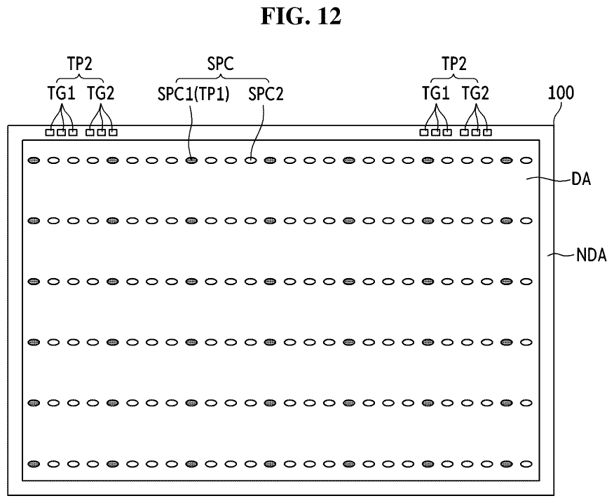

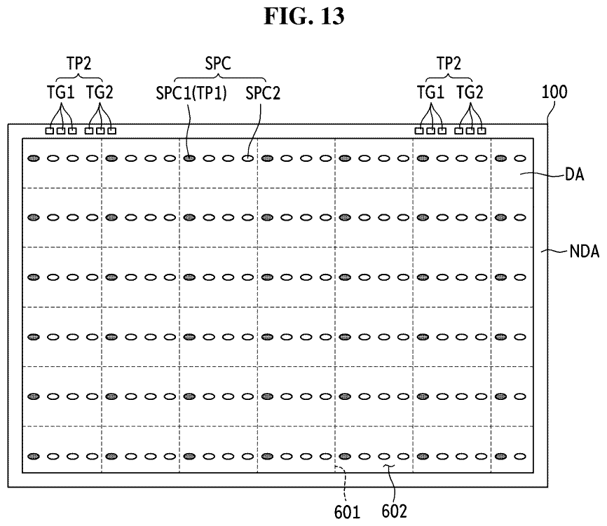

FIGS. 12 and 13 are plan views of a display panel 100 illustrating a first test pattern TP1 and a second test pattern TP2 according to an embodiment.

Referring to FIGS. 12 and 13, a plurality of spacers SPC are disposed in the display area DA of the display panel 100, and a first spacer SPC1, which is at least a portion of the plurality of spacers SPC, includes a first test pattern TP1 for testing deposition defects in each of the first stack ST1 and the second stack ST2.

In an embodiment, at least one second test pattern TP2 for testing deposition defects in each of the first stack ST1 and the second stack ST2 is disposed in the non-display area NDA of the display panel 100. That is, the second test pattern TP2 may be configured in a way such that deposition defects in each of the first stack ST1 and the second stack ST2 may be tested based on the second test pattern TP2.

At least one second test pattern TP2 includes a first test element group (TEG) pattern TG1 deposited in a same process as the lower light emitting layers EML1, EML2, and EML3, and a second TEG pattern TG2 deposited in a same process as the upper light emitting layers EML1′, EML2′, and EML3′.

The first spacer SPC1 is disposed at specified or predetermined intervals within the display area DA.

The display area DA is divided into m×n imaginary partial areas 602, and the first spacer SPC1 is disposed one by one in each of the imaginary partial areas 602. In FIG. 13, the dotted line 601 is an imaginary boundary line dividing the display area DA into the imaginary partial areas 602.

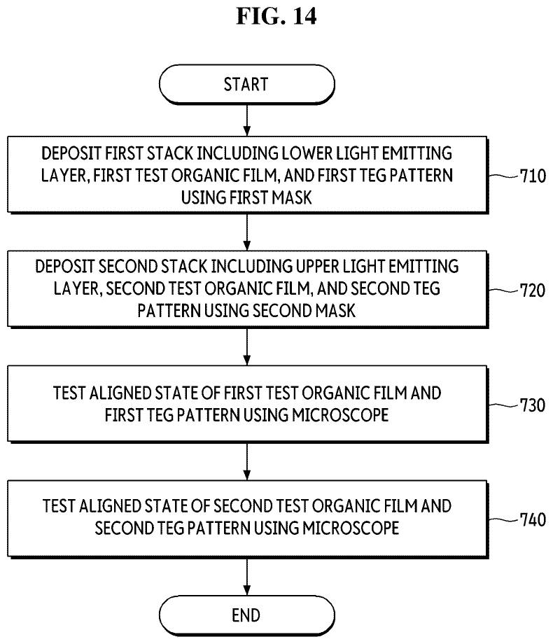

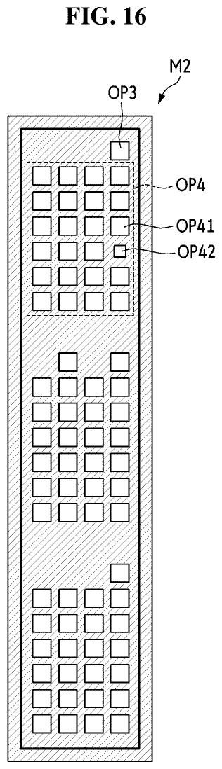

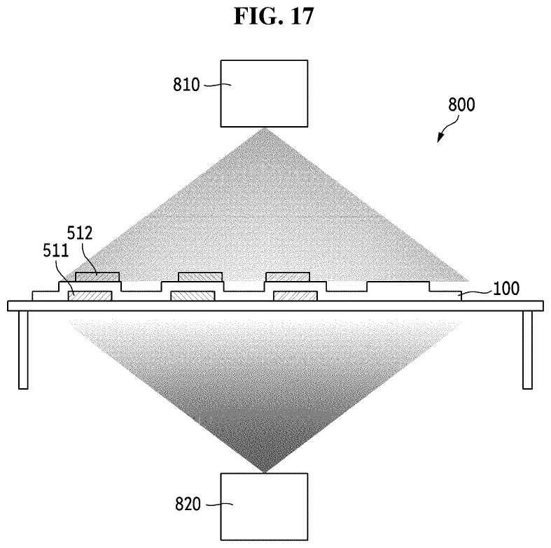

FIG. 14 is a process flowchart illustrating a method of manufacturing a display device 10 according to an embodiment. FIG. 15 is a plan view of a first mask according to an embodiment. FIG. 16 is a plan view of a second mask according to an embodiment. FIG. 17 is a configuration view illustrating test equipment for a display device 10 according to an embodiment.

Hereinafter, a method of manufacturing the display device 10 according to an embodiment will be described with reference to FIGS. 14 to 17.

Referring to FIGS. 14 and 15, in a method of manufacturing a display device 10 according, the first stack ST1 including the lower light emitting layers EML1, EML2, and EML3, the first test organic film 511, and the first TEG pattern TG1 are deposited using a first mask M1 (process 710).

The first mask M1 may be a fine metal mask including or made of a metal material. The first mask M1 may include or be made of a metal such as stainless steel, nickel, cobalt, or an alloy thereof.

The first mask M1 is provided with a first opening OP1 for forming the second test pattern TP2 in the non-display area of the display panel 100. The first opening OP1 may be provided with a plurality of openings for forming a first test element group (TEG) pattern TG1 deposited in a same process as the lower light emitting layers EML1, EML2, and EML3.

The first mask M1 is provided with a second opening OP2 for forming a pattern of an organic light emitting layer in the display area DA of the display panel 100 and forming the first test organic film 511 in the first test pattern TP1. Here, the second opening OP2 is provided a first pattern opening OP21 for forming the pattern of the organic light emitting layer, and a second pattern opening OP22 for forming the first test organic film 511 in the first test pattern TP1. The second pattern opening OP22 may be designed (or shaped) in a way such that the first test organic film 511 is deposited in a circular first shape having a diameter smaller than a length and width of the trench TRC.

Referring to FIGS. 14 and 16, in such an embodiment, the second stack ST2 including the upper light emitting layers EML1′, EML2′, and EML3′, the second test organic film 512, and the second TEG pattern TG2 are deposited using a second mask M2 (process 720).

The second mask M2 may be a fine metal mask including or made of a metal material. The second mask M2 may include or be made of a metal such as stainless steel, nickel, cobalt, or an alloy thereof.

The second mask M2 is provided with a third opening OP3 for forming the second test pattern TP2 in the non-display area of the display panel 100. The third opening OP3 may be provided with a plurality of openings for forming a second test element group (TEG) pattern TG2 deposited in the same process as the upper light emitting layers EML1′, EML2′, and EML3′.

The second mask M2 is provided with a fourth opening OP4 for forming a pattern of an organic light emitting layer in the display area DA of the display panel 100 and forming the second test organic film 512 in the first test pattern TP1. Here, the fourth opening OP4 is provided with a third pattern opening OP41 for forming the pattern of the organic light emitting layer, and a fourth pattern opening OP42 for forming the second test organic film 512 in the first test pattern TP1. The fourth pattern opening OP42 may be designed In a way such that the second test organic film 512 is deposited in a quadrangular second shape having an area smaller than an area of the trench TRC.

Referring to FIGS. 14 and 17, in such an embodiment, an aligned state of the first test organic film 511 and the first TEG pattern TG1 is tested using microscopes 810 and 820 (process 730). In an embodiment, for example, when the deposition process of the lower light emitting layers EML1, EML2, and EML3 is normally performed, the first test organic film 511 deposited on the first test pattern TP1 may be aligned with the center of the reference pattern 513. In an embodiment, for example, when the deposition process of the lower light emitting layers EML1, EML2, and EML3 is abnormally performed, the first test organic film 511 deposited on the first test pattern TP1 may not be aligned with the center of the reference pattern 513.

Referring to FIGS. 14 and 17, in such an embodiment, an aligned state of the second test organic film 512 and the second TEG pattern TG2 is tested using the microscopes 810 and 820 (process 740). In an embodiment, for example, when the deposition process of the upper light emitting layers EML1′, EML2′, and EML3′ is normally performed, the second test organic film 512 deposited on the first test pattern TP1 may be aligned with the center of the reference pattern 513. For example, when the deposition process of the upper light emitting layers EML1′, EML2′, and EML3′ is abnormally performed, the second test organic film 512 deposited on the first test pattern TP1 may not be aligned with the center of the reference pattern 513.

In FIG. 17, an embodiment of a test equipment 800 including an upper microscope 810 and a lower microscope 820 is illustrated, but the disclosure is not limited to such a test method. In an embodiment, for example, the first test pattern TP1 and the second test pattern TP2 may be tested using a 2 photon excitation microscopy method.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a display area, in which a first stack including a lower light emitting layer and a second stack including an upper light emitting layer are disposed, and a non-display area outside the display area,
wherein a pixel defining film partitioning a plurality of light emitting areas and a plurality of spacers disposed at intervals on the pixel defining film are disposed in the display area,
a spacer of the plurality of spacers includes a first test pattern, and
a second test pattern is disposed in the non-display area,
wherein the first test pattern and the second test pattern are configured in a way such that a deposition defect of each of the first stack and the second stack is detected based on the first test pattern and the second test pattern.

2. The display device of claim 1, wherein the first test pattern includes a trench defined on an upper surface of the spacer.

3. The display device of claim 2, wherein the trench has a quadrangular shape in a plan view.

4. The display device of claim 3, wherein the first test pattern further includes:
a first test organic film disposed on the trench in a first shape; and
a second test organic film disposed on the first test organic film in a second shape,
wherein the first test organic film is deposited in a same process as the lower light emitting layer, and the second test organic film is deposited in a same process as the upper light emitting layer.

5. The display device of claim 4, wherein
the first shape is a circular shape with a diameter smaller than a length and a width of the trench in the plan view, and
the second shape is a quadrangular shape having an area smaller than an area of the trench in the plan view.

6. The display device of claim 1, wherein the second test pattern includes:
a first test element group pattern deposited in a same process as the lower light emitting layer, and
a second test element group pattern deposited in a same process as the upper light emitting layer.

7. The display device of claim 1, wherein the plurality of spacers include:
a first spacer including the first test pattern, and
a second spacer which does not include the first test pattern.

8. The display device of claim 7, wherein the first spacer is disposed at predetermined intervals within the display area.

9. The display device of claim 8, wherein
the display area is divided into m×n imaginary partial areas, and
the first spacer is disposed one by one in each of the imaginary partial areas.

10. The display device of claim 1, wherein the first test pattern includes a plurality of trenches defined on an upper surface of the spacer.

11. An electronic device comprising:
a display panel including a display area, in which a first stack including a lower light emitting layer and a second stack including an upper light emitting layer are disposed, and a non-display area outside the display area,
wherein a pixel defining film partitioning a plurality of light emitting areas and a plurality of spacers disposed at intervals on the pixel defining film are disposed in the display area,
a spacer of the plurality of spacers includes a first test pattern, and
a second test pattern is disposed in the non-display area,
wherein the first test pattern and the second test pattern are configured in a way such that a deposition defect of each of the first stack and the second stack is detected based on the first test pattern and the second test pattern.

12. The electronic device of claim 11, wherein the first test pattern includes a trench defined on an upper surface of the spacer.

13. The electronic device of claim 12, wherein the trench has a quadrangular shape in a plan view.

14. The electronic device of claim 13, wherein the first test pattern further includes:
a first test organic film disposed on the trench in a first shape; and
a second test organic film disposed on the first test organic film in a second shape,
wherein the first test organic film is deposited in a same process as the lower light emitting layer, and the second test organic film is deposited in a same process as the upper light emitting layer.

15. The electronic device of claim 14, wherein
the first shape is a circular shape with a diameter smaller than a length and a width of the trench in the plan view, and
the second shape is a quadrangular shape having an area smaller than an area of the trench in the plan view.

16. The electronic device of claim 11, wherein the second test pattern includes:
a first test element group pattern deposited in a same process as the lower light emitting layer, and
a second test element group pattern deposited in a same process as the upper light emitting layer.

17. The electronic device of claim 11, wherein the plurality of spacers include:
a first spacer including the first test pattern, and
a second spacer which does not include the first test pattern.

18. The electronic device of claim 17, wherein the first spacer is disposed at predetermined intervals within the display area.

19. The electronic device of claim 18, wherein the display area is divided into m×n imaginary partial areas, and
the first spacer is disposed one by one in each of the imaginary partial areas.

20. The electronic device of claim 11, wherein the first test pattern includes a plurality of trenches defined on an upper surface of the spacer.
